(19) United States
(12) Patent Application Publication
(10) Pub. No.: US 2007/0096181 A1
(43) Pub. Date: May 3, 2007

(54) FLEXIBLE MEMORY MODULE

(75) Inventor: Shih-Hsiung Lien, Shihlin District, Taipei City (TW)

Correspondence Address: OPTIMUM CARE INTERNATIONAL TECH. INC., P.O. BOX 108-00403, TAIPEI, TW

(73) Assignee: Optimum Care International Tech. Inc., Taipei City (TW)

(21) Appl. No.: 11/379,807

(22) Filed: Apr. 24, 2006

(30) Foreign Application Priority Data
Oct. 27, 2005 (TW) 094218593

(51) Int. Cl. H01L 29/94; H01L 27/108; H01L 29/76; H01L 31/119

(52) U.S. Cl. 257/296

(57) ABSTRACT

A flexible memory module includes a substrate formed of a printed circuit board and electrically connectable to a insertion slot of a connector, a flexible board extension, which is fixedly provided at the rear side of the substrate and turned backwards and covered over the substrate to reduce surface space occupation after connection of the substrate to the insertion slot of the connector, and a plurality of memory chips respectively installed in the substrate and the flexible board extension.

This application claims the priority benefit of Taiwan patent application number 094218593 filed on Oct. 27, 2005.

### BACKGROUND OF THE INVENTION

1. Field of the Invention

The present invention relates to a memory module and more particularly, to such a memory module, which has a flexible board extension extended from one side of the substrate to carry added memory chips without extra installation space.

2. Description of the Related Art

Following fast development of electronic industry and electronic technology, more and more advanced electronic products are used in our daily life to improve the working efficiency and the living quality. Many different electronic products, more particularly, computers, communication apparatus and consumer electronics use different memory devices for storing and transferring data.

Many memory modules have been disclosed and have appeared on the market. These memory modules include SIMM (Single In-Line Memory Module), DIMM (Dual In-Line Memory Module), RIMM (Direct Rambus Memory Module), and etc. These memory modules may carry 8 or 4 memory chips on one single side, or 16 memory chips on two sides. When wishing to increase the memory capacity of a memory module, the memory capacity of each memory chip must be upgraded. Further, following the development of manufacturing techniques, electronic products are made to have light, thin, short and small characteristics. In order to fit small size electronic products, SO DIMM (Small Outline Dual In-Line Memory Module) is disclosed. This memory module carries only 4 memory chips on one side. This design has no space for extra memory chips. Increasing the memory capacity of this design of memory module must firstly increase the memory capacity of each individual memory chip.

### SUMMARY OF THE INVENTION

The present invention has been accomplished under the circumstances in view. It is the main object of the present invention to provide a flexible memory module, which allows installation of added memory chips without increasing the installation space. To achieve this and other objects of the present invention, the flexible memory module comprises a substrate, which is formed of a printed circuit board and electrically connectable to a insertion slot of a connector, a flexible board extension, which is fixedly provided at the rear side of the substrate and turned backwards and covered over the substrate to reduce surface space occupation after connection of the substrate to the insertion slot of the connector, and a plurality of memory chips respectively installed in the substrate and the flexible board extension. In an alternate form of the present invention, the flexible memory module comprises two substrates (printed circuit boards), a flexible connection strip connected between the substrates, and memory chips respectively installed in the substrate. The flexible connection strip allows the two substrates to be arranged in a stack after connection of the flexible memory module to a insertion slot of a connector.

### BRIEF DESCRIPTION OF THE DRAWINGS

FIG. 1 is a perspective view of a flexible memory module in accordance with a first embodiment of the present invention.

FIG. 2 is a schematic drawing showing an installation example of the flexible memory module according to the first embodiment of the present invention (I).

FIG. 3 is a schematic drawing showing an installation example of the flexible memory module according to the first embodiment of the present invention (II).

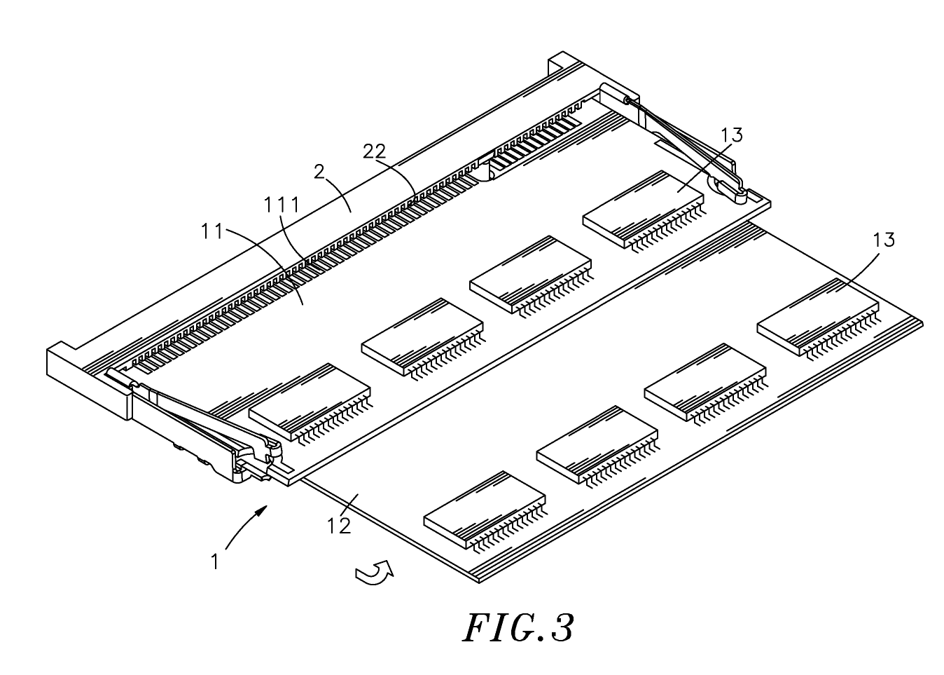

FIG. 4 is a schematic drawing showing an installation example of the flexible memory module according to the first embodiment of the present invention (III).

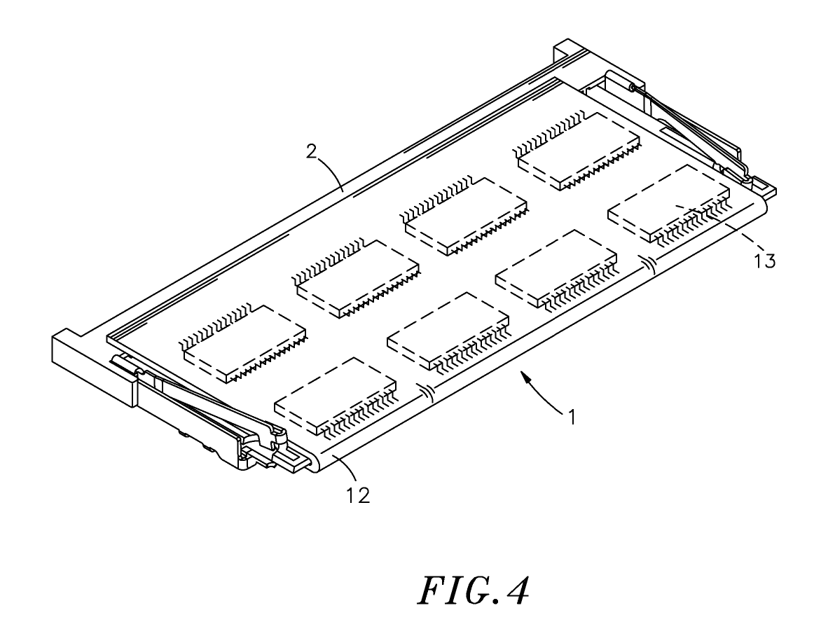

FIG. 5 is a schematic drawing showing an installation example of the flexible memory module according to a second embodiment of the present invention (I).

FIG. 6 is a schematic drawing showing an installation example of the flexible memory module according to the second embodiment of the present invention (II).

FIG. 7 is an elevational view of a flexible memory module in accordance with a third embodiment of the present invention.

### DETAILED DESCRIPTION OF THE PREFERRED EMBODIMENT

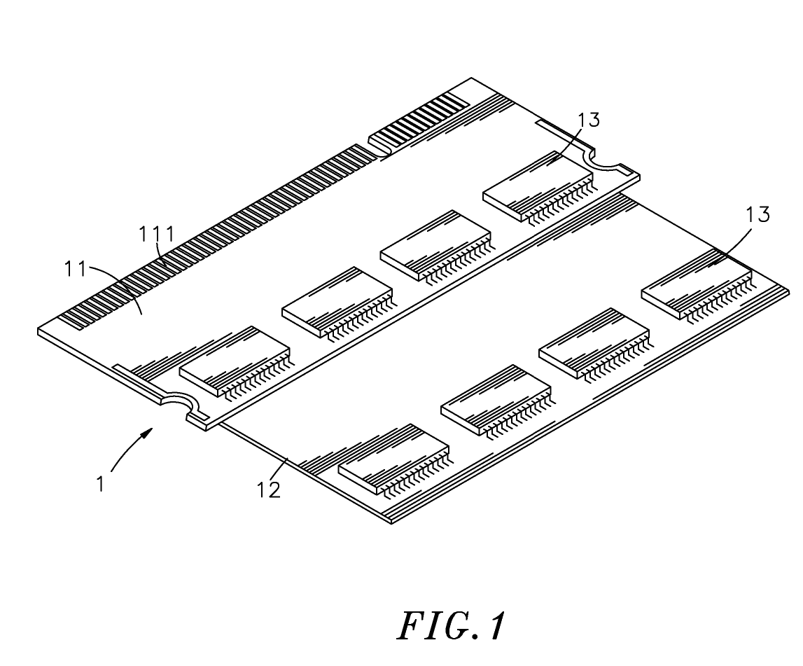

Referring to FIG. 1, a flexible memory module 1 in accordance with a first embodiment of the present invention is shown comprised of a substrate 11, a flexible board extension 12, and a plurality of memory chips 13.

The substrate 11 according to this embodiment is a printed circuit board having a control circuit (not shown) and a plurality of contacts 111 at one side.

The flexible board extension 12 is connected to one side of the substrate 11 away from the contacts 111, carrying a control circuit (not shown).

The memory chips 13 are respectively installed in the substrate 11 and the flexible board extension 12. Further, the memory chips 13 can be DRAM, EDO DRAM, SDRAM, DDR SDRAM, DDRII SDRAM, DDRIII SDRAM, SRAM or Flash chips.

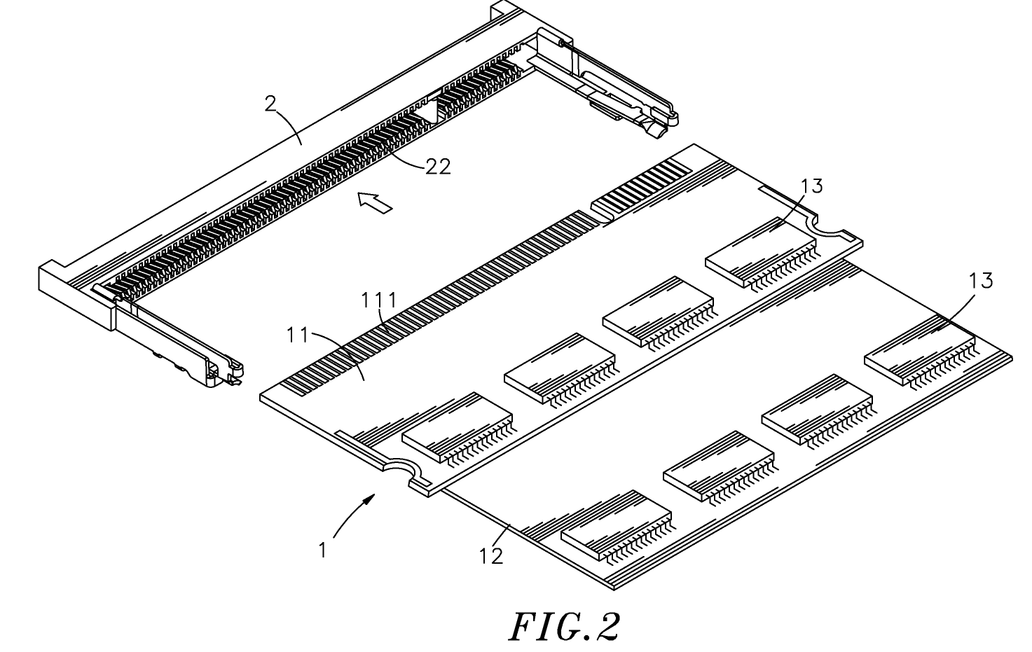

Referring to FIGS. 2˜4, during the use of the flexible memory module 1, the substrate 11 is inserted into a insertion slot 22 of a connector 2 to force the contacts 111 of the substrate 11 into contact with respective contacts in the insertion slot 22 of the connector 2. After connection of the substrate 11 to the insertion slot 22 of the connector 2, the user can then bend the flexible board extension 12 backwards toward the connector 2 and cover the flexible board extension 12 on the top side of the substrate 11, thereby reducing surface space occupation. Because the substrate 11 and flexible board extension 12 of the flexible memory module 1 can be arranged in a stack, the invention doubles the amount of memory chips 13 without increasing much the installation space. Therefore, the flexible memory module 1 of the present invention fits the requirement for an electronic device having light, thin, short and small characteristics.

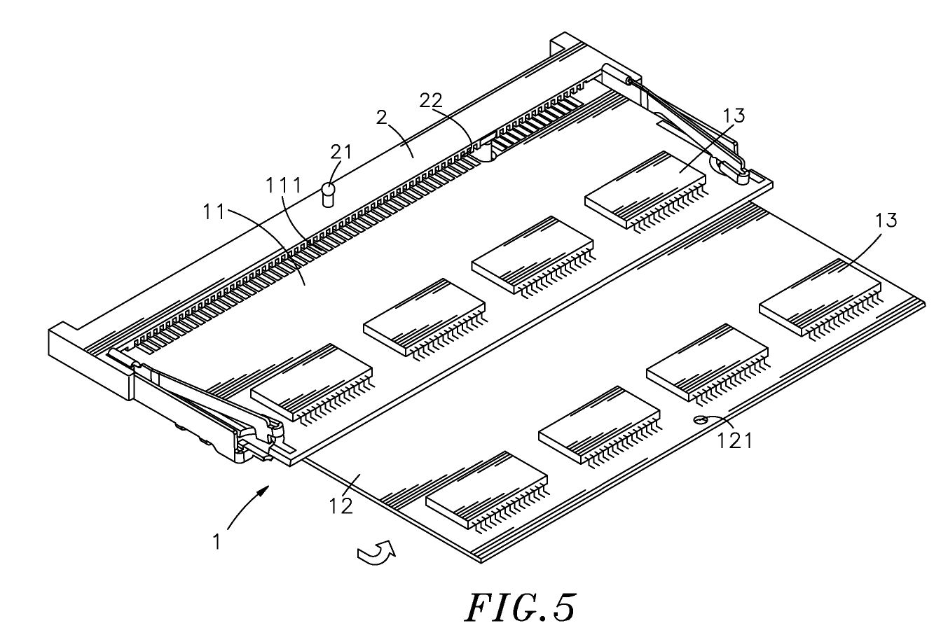

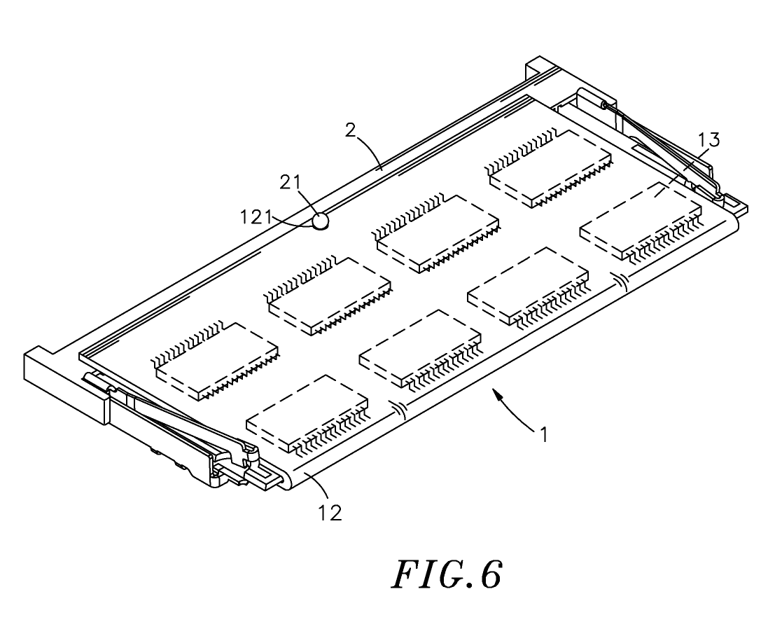

FIGS. 5 and 6 show a flexible memory module in accordance with a second embodiment of the present invention. This embodiment is substantially similar to the aforesaid first embodiment with the exception that the flexible board extension 12 has a retaining hole 121 on the remote side (the side away from the contact 111) corresponding to a protruding point 21 of the connector 2. When turned the flexible board extension 12 backwards toward the connector 2 over the top side of the substrate 11, the retaining hole 121 is forced into engagement with the protruding point 21 at the connector 2, and therefore the flexible board extension 12 is kept overlapped on the substrate 11.

In the aforesaid second embodiment, the flexible board extension 12 is made to have the retaining hole 121 for securing to the protruding point 21 at the connector 2. Alternatively, snap fastener or any of a variety of other fastening means may be used to detachably secure the free end of the flexible board extension 12 to the connector 2.

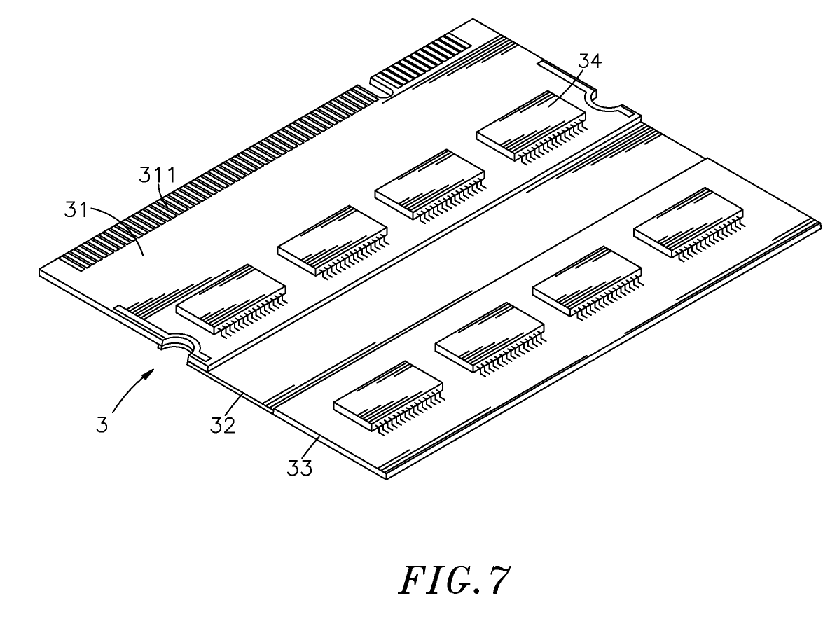

FIG. 7 shows a flexible memory module 3 in accordance with a third embodiment of the present invention. According to this embodiment, the flexible memory module 3 comprises a first substrate 31, which has a control circuit (not shown) and a plurality of contacts 311 at one side, a second substrate 33, which has a control circuit (not shown), a flexible connection strip 32, which has a control circuit (not shown), a first lateral side fixedly connected to one side of the first substrate 31 away from the contacts 311 and a second lateral side fixedly connected to one side of the second substrate 33, and a plurality of memory chips 34 respectively installed in the first substrate 31 and the second substrate 33.

By means of the flexible connection strip 32, the first substrate 31 and the second substrate 33 can be turned toward each other and arranged in a stack to reduce the installation space. Further, a male fastening member (not shown) and a female fastening member (not shown) may be respectively provided at the first substrate 31 and the second substrate 32 and fastened to each other to hold the flexible memory module 3 in a folded status.

Similar to the aforesaid first embodiment, the memory chips 34 of this third embodiment can be DRAM, EDO DRAM, SDRAM, DDR SDRAM, DDRII SDRAM, DDRIII SDRAM, SRAM or Flash chips.

A prototype of flexible memory module has been constructed with the features of FIGS. 1˜7. The flexible memory module functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A flexible memory module electrically connectable to a connector, comprising:
a substrate, said substrate having control circuit means carried thereof and a plurality of contacts arranged at one peripheral side thereof and electrically connected to the control circuit means of said substrate for connection to respective contacts in a insertion slot of said connector;
a flexible board extension, said flexible board extension having one lateral side fixedly connected to one side of said substrate away from the contacts of said substrate for enabling said flexible board extension to be turned backwards and covered over said substrate, and control circuit means; and
a plurality of memory chips respectively installed in said substrate and said flexible board extension and respectively electrically connected to the control circuit means of said substrate and said flexible board extension.

2. The flexible memory module as claimed in claim 1, wherein said memory chips are selected from DRAM, EDO DRAM, SDRAM, DDR SDRAM, DDRII SDRAM, DDRIII SDRAM, SRAM or Flash chips.

3. The flexible memory module as claimed in claim 1, further comprising fastening means adapted to secure said flexible board extension to said connector to which the flexible memory module is connected after said flexible board extension has been turned backwards and covered over said substrate.

4. A flexible memory module electrically connectable to a connector, comprising:
a first substrate, said first substrate having control circuit means carried thereof and a plurality of contacts arranged at one peripheral side thereof and electrically connected to the control circuit means of said first substrate for connection to respective contacts in a insertion slot of said connector;
a second substrate, said second substrate having control circuit means;
a flexible connection strip, said flexible connection strip having a first lateral side fixedly connected to one lateral side of said first substrate away from the contacts of said first substrate and a second lateral side fixedly connected to one lateral side of said second substrate for enabling said second substrate to be turned backwards and covered over said first substrate, and control circuit means; and
a plurality of memory chips respectively installed in said first substrate and said second substrate and respectively electrically connected to the control circuit means of said first substrate and said second substrate.

5. The flexible memory module as claimed in claim 4, wherein said memory chips are selected from DRAM, EDO DRAM, SDRAM, DDR SDRAM, DDRII SDRAM, DDRIII SDRAM, SRAM or Flash chips.

6. The flexible memory module as claimed in claim 4, further comprising fastening means adapted to secure said second substrate to the connector to which the flexible memory module is connected after said second substrate has been turned backwards and covered over said first substrate.
